(19) United States
(12) Patent Application Publication
(10) Pub. No.: US 2025/0176278 A1
(43) Pub. Date: May 29, 2025

(54) ELECTROSTATIC DISCHARGE PROTECTION DEVICE

(71) Applicant: MEDIATEK INC., Hsinchu City (TW)

(72) Inventors: Tzung-Lin LI, Hsinchu City (TW); Yuan-Fu CHUNG, Hsinchu City (TW); Tung-Hsing LEE, Hsinchu City (TW)

(21) Appl. No.: 18/926,751

(22) Filed: Oct. 25, 2024

Related U.S. Application Data
(60) Provisional application No. 63/603,683, filed on Nov. 29, 2023.

(51) Int. Cl. H01L 27/02; H01L 29/861

(52) U.S. Cl. CPC H10D 89/814; H10D 8/00; H10D 89/711

(57) ABSTRACT

An electrostatic discharge protection device is provided. The electrostatic discharge protection device includes a semiconductor substrate, a first well region, first, second and third doped regions, and a gate structure. The first well region having a first conductivity type is located in the semiconductor substrate. The first and second doped region having a second conductivity type are located on the first well region. The third doped region having the first conductivity type is located on the first well region. The second and third doped regions are located on opposite sides of the first doped region. The gate structure is disposed on a portion of the semiconductor substrate between the first and second doped regions. A conductivity type of the gate structure is different from a conductivity type of the first and second doped regions. The gate structure is electrically connected to the first and third doped regions.

### CROSS REFERENCE TO RELATED APPLICATIONS

This application claims the benefit of U.S. Provisional Application No. 63/603,683, filed Nov. 29, 2023, the entirety of which is incorporated by reference herein.

### BACKGROUND OF THE INVENTION

### Field of the Invention

The present disclosure relates to an electrostatic discharge protection device, and, in particular, to the structure of an electrostatic discharge protection device having low leakage current in standby mode.

### Description of the Related Art

Electrostatic discharge (ESD) is a phenomenon in which a charge is released and transferred between a semiconductor device (e.g., a semiconductor chip) and an external object (e.g., a human body). In an ESD, a large amount of charge is released in a short time, and so the energy from the ESD is much higher than the bearing capacity of the semiconductor device, which may result in a temporary functional failure or even permanent damage to the semiconductor device. Therefore, an ESD clamp circuit is built into semiconductor devices to offer an electrostatic discharge path that effectively protects the semiconductor device, so that the reliability and service life of the semiconductor device is maintained. When the semiconductor device is in normal operation, however, the leakage current in conventional ESD protection circuits may cause the semiconductor device to suffer from poor electrical performance.

### BRIEF SUMMARY OF THE INVENTION

An embodiment of the disclosure provides an electrostatic discharge protection device. The electrostatic discharge protection device includes a semiconductor substrate, a first well region, a first doped region, a second doped region, a third doped region and a gate structure. The first well region having a first conductivity type is located in the semiconductor substrate. The first doped region having a second conductivity type is located on the first well region. The second doped region having the second conductivity type is located on the first well region. The first doped region and the second doped region are arranged side-by-side and spaced apart from each other. The third doped region having the first conductivity type is located on the first well region. The second doped region and the third doped region are located on opposite sides of the first doped region. The gate structure is disposed on the first well region and located on a portion of the semiconductor substrate between the first doped region and the second doped region. A conductivity type of the gate structure is different from a conductivity type of the first doped region and the second doped region. The gate structure is electrically connected to the first doped region and the third doped region.

An embodiment of the disclosure provides an electrostatic discharge protection device. The electrostatic discharge protection device includes a semiconductor substrate, a first well region, and a first type metal-oxide-semiconductor field-effect transistor. The first well region having a first conductivity type is located in the semiconductor substrate. The first type metal-oxide-semiconductor field-effect transistor is formed in the first well region. A conductivity type of a gate of the first type metal-oxide-semiconductor field-effect transistor is different from a conductivity type of a source and a drain of the first type metal-oxide-semiconductor field-effect transistor. The gate and a bulk of the first type metal-oxide-semiconductor field-effect transistor are electrically connected to a first terminal.

### BRIEF DESCRIPTION OF THE DRAWINGS

The present invention can be more fully understood by reading the subsequent detailed description and examples with references made to the accompanying drawings, wherein:

FIG. 1 is a schematic connection diagram of an electrostatic discharge protection device in accordance with some embodiments of the disclosure;

FIG. 2 is a schematic cross-sectional view of the electrostatic discharge protection device of FIG. 1 in accordance with some embodiments of the disclosure;

FIG. 3 is an equivalent discharge circuit diagram of the electrostatic discharge protection device in accordance with some embodiments of the disclosure shown in FIG. 2, which shows the equivalent discharge circuit when an electrostatic discharge event occurs between the power supply terminal VDD and the ground terminal VSS;

FIG. 4 is a schematic cross-sectional view showing the parasitic elements of the equivalent discharge circuit of FIG. 3 at the corresponding positions of the electrostatic discharge protection device of FIG. 2;

FIG. 5 is a schematic cross-sectional view of the electrostatic discharge protection device of FIG. 1 in accordance with some embodiments of the disclosure;

FIG. 6 is an equivalent discharge circuit diagram of the electrostatic discharge protection device in accordance with some embodiments of the disclosure shown in FIG. 5, which shows the equivalent discharge circuit when an electrostatic discharge event occurs between the power supply terminal VDD and the ground terminal VSS; and

FIG. 7 is a schematic cross-sectional view showing the parasitic elements of the equivalent discharge circuit of FIG. 6 at the corresponding positions of the electrostatic discharge protection device of FIG. 5.

### DETAILED DESCRIPTION OF THE INVENTION

The following description is made for the purpose of illustrating the general principles of the invention and should not be taken in a limiting sense. The scope of the invention is best determined by reference to the appended claims.

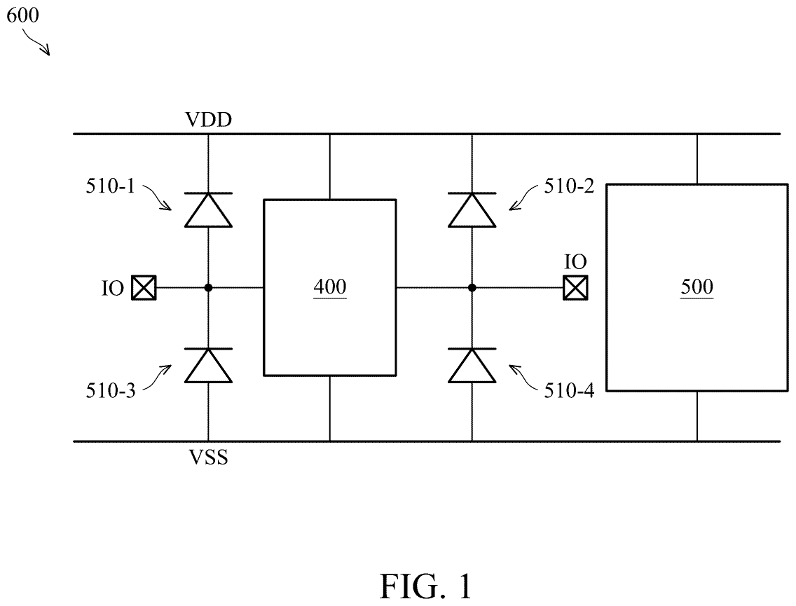

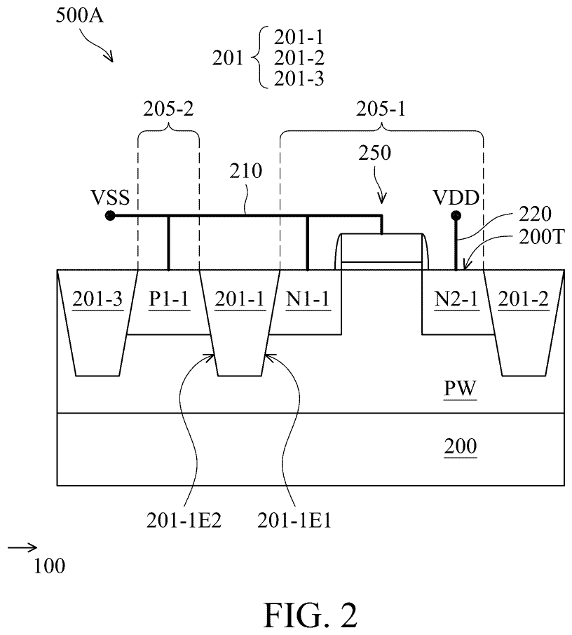

FIG. 1 is a schematic connection diagram of an electrostatic discharge (ESD) protection device 500 (including electrostatic discharge protection devices 500A and 500B shown in the following figures) disposed in a system 600 in accordance with some embodiments of the disclosure. FIG. 2 is a schematic cross-sectional view of the ESD protection device 500A of FIG. 1 in accordance with some embodiments of the disclosure. The system 600 includes an internal circuit 400 and the electrostatic discharge (ESD) protection device 500 used to protect the internal circuit 400. The internal circuit 400 is electrically connected to input/output terminals IO, a power supply terminal VDD and a ground terminal VSS of the system 600. In some embodiments, the ESD protection device 500 is used as a power clamp circuit. The ESD protection device 500 is electrically connected to the power supply terminals VCC and the ground terminals VSS of the system 600 to prevent an electrostatic discharge current from flowing through the circuit under protection. In addition, the system 600 may further include ESD protection devices composed of diodes 510-1, 510-2, 510-3 and 510-4. For example, the diodes 510-1 and 510-2 are electrically connected between the input/output terminal IO and the power supply terminal VDD of the system 600 to prevent an electrostatic discharge current from flowing through the internal circuit 400. The diodes 510-3 and 510-4 are electrically connected between the input/output terminal IO and the ground terminal VSS of the system 600 to prevent an electrostatic discharge current from flowing through the internal circuit 400.

As shown in FIG. 2, the ESD protection device 500A includes a semiconductor substrate 200, a first well region PW, a first doped region N1-1, a second doped region N2-1, and a third doped region P1-1 located in the first well region PW, and a gate structure 250 located on the semiconductor substrate 200.

In some embodiments, the semiconductor substrate 200 may be a semiconductor substrate having a conductivity type that is either P-type or N-type. In some embodiments, the semiconductor substrate 200 is P-type. The first well region PW is located in the semiconductor substrate 200. In some embodiments, the first well region PW has a first conductivity type. For example, when the first conductivity type is P-type, the first well region PW is a P-type well region PW. In addition, the first well region PW and the semiconductor substrate 200 may have the same or opposite conductivity types.

The first well region PW has one or more heavily doped regions formed thereon. For example, the first doped region N1-1 (i.e., a first heavily doped region N1-1), the second doped region N2-1 (i.e., a second heavily doped region N2-1), and the third doped region P1-1 (i.e., a third heavily doped region P1-1) are located directly on different portions of the first well region PW. The second doped region N2-1 and the third doped region P1-1 are located on opposite sides of the first doped region N1-1 in a direction 100 (the direction substantially parallel to a top surface 200T of the semiconductor substrate 200). In some embodiments, the first doped region N1-1 and the second doped region N2-1 have the same conductivity type. The conductivity type of the first doped region N1-1 and the second doped region N2-1 is opposite to that of the first well region PW and the third doped region P1-1. The conductivity type of the third doped region P1-1 is the same as that of the first well region PW.

In some embodiments, the first doped region N1-1 and the second doped region N2-1 have a second conductivity type, and the third doped region P1-1 has the first conductivity type. The first conductivity type may be opposite to the second conductivity type. For example, when the first conductivity type is P-type and the second conductivity type is N-type, the first doped region N1-1 is an N-type heavily doped region N1-1, the second doped region N2-1 is an N-type heavily doped region N2-1, and the third doped region P1-1 is a P-type heavily doped region P1. In some embodiments, the first doped region N1-1 and the second doped region N2-1 may have the same doping concentration. In some embodiments, the doping concentration of third doped region P1-1 is greater than that of the first well region PW.

The electrostatic discharge protection device 500A also includes isolation features 201 (including isolation features 201-1, 201-2 and 201-3) such as a shallow trench isolation trench isolations (STIs) disposed in the first well region PW in the semiconductor substrate 200. The isolation features 201-1, 201-2 and 201-3 may define active regions 205-1 and 205-2. As shown in FIG. 2, the first doped region N1-1 and the second doped region N2-1 may be arranged side-by-side and located in the same active region 205-1 defined by the isolation features 201-1 and 201-2. The first doped region N1-1 and the second doped region N2-1 may be adjacent to the different isolation features 201-1 and 201-2. In addition, the first doped region N1-1 and the second doped region N2-1 may be spaced apart from each other in the direction 100. Furthermore, there is no isolation feature 201 between the first doped region N1-1 and the second doped region N2-1 in the direction 100.

As shown in FIG. 2, the third doped region P1-1 is located in the active region 205-2 defined by the isolation features 201-1 and 201-3. The first doped region N1-1 and the third doped region P1-1 may be arranged side-by-side and spaced apart from each other by the isolation feature 201-1 in the first well region PW. In addition, opposite side surfaces 201-1E1 and 201-1E2 of the isolation feature 201-1 are respectively adjacent to the first doped region N1-1 and the third doped region P2.

The gate structure 250 is disposed on the first well region PW. In addition, the gate structure 250 is located on a portion of the semiconductor substrate 200 between the first doped region N1-1 and the second doped region N2-1 in the direction 100 (the lateral direction). In addition, the gate structure 250 is adjacent to the first doped region N1-1 and the second doped region N2-1. In some embodiments, the gate structure 250 includes a gate dielectric layer (not shown) disposed on the semiconductor substrate 200, a gate electrode layer (not shown) disposed above the gate dielectric layer, and gate spacers (not shown) disposed on opposite side surfaces of the gate dielectric layer and opposite side surfaces of the gate electrode layer.

In some embodiments, the gate electrode layer of the gate structure 250 may be implanted with dopants. Alternatively, the gate electrode layer of the gate structure 250 may be formed without doping (undoped). In some embodiments, the conductivity type of the gate electrode layer of the gate structure 250 is different from the conductivity type of the first doped region N1-1 and the second doped region N2-1. For example, when the first doped region N1-1 and the second doped region N2-1 have the second conductivity type (e.g., N-type), the gate electrode layer of the gate structure 250 has the first conductivity type (e.g., P-type) or I-type (intrinsic).

As shown in FIG. 2, the electrostatic discharge protection device 500A is electrically connected between the ground terminal VSS and the power supply terminal VDD. The gate structure 250 is electrically connected to the first doped region N1-1 and the third doped region P1-1 directly by a conductive line 210. The conductive line 210 is electrically connected to the ground terminal VSS. In other words, the gate structure 250, the first doped region N1-1 and the third doped region P1-1 are electrically connected to the ground terminal VSS. In addition, the second doped region N2-1 is electrically connected to the power supply terminal VDD directly by a conductive line 220.

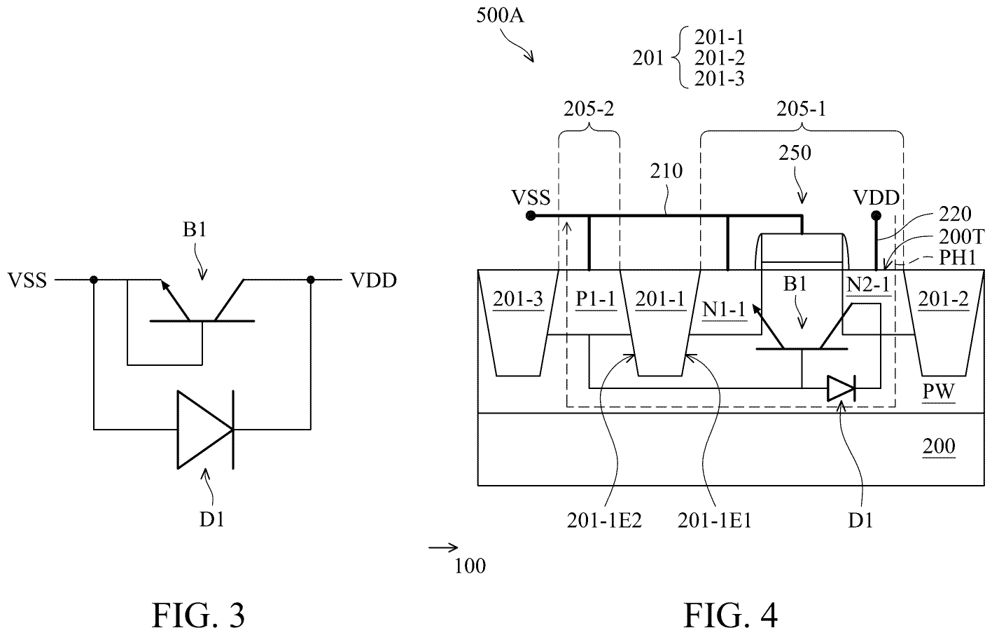

FIG. 3 is an equivalent discharge circuit diagram of the electrostatic discharge protection device 500A in accordance with some embodiments of the disclosure shown in FIG. 2, which shows the equivalent discharge circuit when an electrostatic discharge (ESD) event occurs between the power supply terminal VDD and the ground terminal VSS. FIG. 4 is a schematic cross-sectional view showing the parasitic elements of the equivalent discharge circuit of FIG. 3 at the corresponding positions of the electrostatic discharge protection device 500A of FIG. 2. As shown in FIGS. 3 and 4, the equivalent discharge circuit in a condition that the electrostatic discharge event occurs between the power supply terminal VDD and the ground terminal VSS includes a parasitic bipolar junction transistor (BJT) B1 (for example, a parasitic NPN BJT) formed by the first doped region N1-1, the first well region PW and the second doped region N2-1. Emitter, base and collector of the parasitic bipolar junction transistor B1 are respectively formed by the first doped region N1-1, the first well region PW and the second doped region N2-1. The equivalent discharge circuit further includes a parasitic diode D1 formed by the second doped region N2-1, the first well region PW and the third doped region P1-1. Anode and cathode of the parasitic diode D1 are respectively formed by the third doped region P1-1/the first well region PW and the second doped region N2-1.

As shown in FIGS. 3 and 4, in this embodiment, the base (the first well region PW) of the parasitic bipolar junction transistor B1 is electrically connected to the emitter (the first doped region N1-1) of the parasitic bipolar junction transistor B1. The parasitic diode D1 is connected between the emitter (the first doped region N1-1) and the collector (the second doped region N2-1) of the parasitic bipolar junction transistor B1. More specifically, the anode (the third doped region P1-1 and the first well region PW) of the parasitic diode D1 is electrically connected to the emitter (the first doped region N1-1) and the base (the first well region PW) of the parasitic bipolar junction transistor B1. The cathode (the second doped region N2-1) of the parasitic diode D1 is electrically connected to the collector (the second doped region N2-1) of the parasitic bipolar junction transistor B1. The emitter (the first doped region N1-1) and the base (the first well region PW) of the parasitic bipolar junction transistor B1 and the anode (the third doped region P1-1 and the first well region PW) of the parasitic diode D1 are electrically connected to the ground terminal VSS by the conductive line 210. The collector (the second doped region N2-1) of the parasitic bipolar junction transistor B1 and the cathode (the second doped region N2-1) of the parasitic diode D1 are electrically connected to the power supply terminal VDD by the conductive line 220.

On the other hand, the gate structure 250, the first well region PW, the first doped region N1-1, the second doped region N2-1 and the third doped region P1-1 may collectively form a first type metal-oxide-semiconductor field-effect transistor (MOS FET). The first type metal-oxide-semiconductor field-effect transistor (MOS FET) is formed in the first well region PW. In the first type metal-oxide-semiconductor field-effect transistor, the gate structure 250 serves as the gate of the first type metal-oxide-semiconductor field-effect transistor. The first doped region N1-1 may serve as the source of the first type metal-oxide-semiconductor field-effect transistor. The second doped region N2-1 may serve as the drain of the first type metal-oxide-semiconductor field-effect transistor. The third doped region P1-1 and the first well region PW may serve as the base (also called bulk) of the first type metal-oxide-semiconductor field-effect transistor.

In this embodiment, the gate (the gate structure 250), the source (the first doped region N1-1) and the bulk (the third doped region P1-1 and the first well region PW) of the first type metal-oxide-semiconductor field-effect transistor are electrically connected to the ground terminal VSS by the conductive line 210. The drain (the second doped region N2-1) of the first type metal-oxide-semiconductor field-effect transistor is electrically connected to the power supply terminal VDD by the conductive line 220. In this embodiment, the first conductivity type is P-type, the second conductivity type is N-type, and the first type metal-oxide-semiconductor field-effect transistor (MOS FET) is an N-type metal-oxide-semiconductor field-effect transistor (NMOS FET). The electrostatic discharge protection device 500A may serve as a gate-grounded N-type metal-oxide-semiconductor field-effect transistor (GG NMOS FET).

In this embodiment, the source (the first doped region N1-1) and the drain (the second doped region N2-1) of the first type metal-oxide-semiconductor field-effect transistor (NMOS FET) and the first well region PW form the parasitic bipolar junction transistor B1. The drain (the second doped region N2-1) of the first type metal-oxide-semiconductor field-effect transistor (NMOS FET) and the bulk (the third doped region P1-1 and the first well region PW) of the first type metal-oxide-semiconductor field-effect transistor (NMOS FET) form a parasitic diode D1.

Since the conductivity type of the gate electrode layer of the gate structure 250 is different from the conductivity type of the source (the first doped region N1-1) and the drain (the second doped region N2-1) of the first type metal-oxide-semiconductor field-effect transistor structure, the first type MOS FET structure may have a higher threshold voltage (Vt) in standby mode. The off current (Ioff) and drain-to-source leakage may be further reduced without additional fabrication cost (e.g., extra masks or larger device area).

When an electrostatic discharge event occurs at the power supply terminal VDD and the ground terminal VSS is grounded (or different input/output terminals IO to the power supply terminal VDD/the ground terminal VSS stress conditions), the base (the first well region PW)-emitter (the first doped region N1-1) junction of the parasitic bipolar junction transistor B1 (the parasitic NPN BJT) will be in forward bias condition, and the reverse-biased PN junction of the parasitic diode D1 will breakdown. In general, the parasitic bipolar junction transistor B1 has lower trigger voltage than the breakdown voltage of the parasitic diode D1. Therefore, the parasitic bipolar junction transistor B1 is triggered to ON to form a current path PH1 from the power supply terminal VDD, through the parasitic diode D1, and to the ground terminal VSS to discharge the electrostatic charges away from the internal circuit 400.

When an electrostatic discharge event occurs at the ground terminal VSS and the power supply terminal VDD is grounded, the parasitic diode D1 will be in forward bias condition to form a current path from the ground terminal VSS, through the parasitic diode D1, and to the power supply terminal VDD to discharge the electrostatic charges away from the internal circuit 400. The electrostatic discharge protection device 500A may provide bi-directional ESD protection.

When the internal circuit 400 in the system 600 is in normal operation (no electrostatic discharge event occurs), the electrostatic discharge protection device 500A is in the off-state. The base (the first well region PW)-emitter (the first doped region N1-1) junction of the parasitic bipolar junction transistor B1 is not in forward bias condition. In addition, the parasitic diode D1 is in reverse bias condition. Therefore, the parasitic bipolar junction transistor B1 and the parasitic diode D1 will not be triggered to ON. Furthermore, the electrostatic discharge protection device 500A is composed of the gate-grounded N-type metal-oxide-semiconductor field-effect transistor (GG NMOS FET) with higher threshold voltage (Vt) in standby mode. The off current (Ioff) and drain-to-source leakage of the electrostatic discharge protection device 500A may be further reduced.

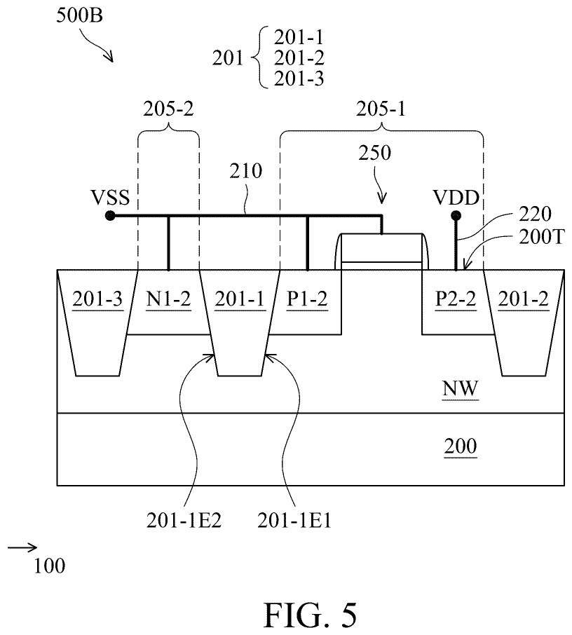

FIG. 5 is a schematic cross-sectional view of the electrostatic discharge protection device 500B of FIG. 1 in accordance with some embodiments of the disclosure. Elements of the embodiments hereinafter, that are the same or similar as those previously described with reference to FIGS. 2 and 4, are not repeated for brevity. One of the differences between the electrostatic discharge protection device 500A shown in FIG. 2 and the electrostatic discharge protection device 500B shown in FIG. 5 is that the electrostatic discharge protection device 500B may have the conductivity type opposite to the electrostatic discharge protection device 500A. For example, in the electrostatic discharge protection device 500A, the elements having the first conductivity type are P-type elements, and the elements having the second conductivity type are N-type elements. In the electrostatic discharge protection device 500B, the elements having the first conductivity type are N-type elements, and the elements having the second conductivity type are P-type elements.

As shown in FIG. 5, the ESD protection device 500B includes the semiconductor substrate 200, a first well region NW, a first doped region P1-2, a second doped region P2-2, and a third doped region N1-2 located in the first well region NW, and a gate structure 250 located on the semiconductor substrate 200.

As shown in FIG. 5, the first well region NW is located in the semiconductor substrate 200. In some embodiments, the first well region PW has the first conductivity type. In this embodiment, the first conductivity type is N-type, and the first well region NW is an N-type well region NW. In addition, the first well region NW and the semiconductor substrate 200 may have the same or opposite conductivity types.

The first well region NW has one or more heavily doped regions formed thereon. For example, the first doped region P1-2 (i.e., a first heavily doped region P1-2), the second doped region P2-2 (i.e., a second heavily doped region P2-2), and the third doped region N1-2 (i.e., a third heavily doped region N1-2) are located directly on different portions of the first well region NW. The second doped region P2-2 and the third doped region N1-2 are located on opposite sides of the first doped region P1-2. In some embodiments, the conductivity type of the first doped region P1-2 and the second doped region P2-2 is opposite to that of the first well region NW and the third doped region N1-2. The conductivity type of the third doped region N1-2 is the same as that of the first well region NW.

In some embodiments, the first doped region P1-2 and the second doped region P2-2 have the second conductivity type, and the third doped region N1-2 has the first conductivity type. The first conductivity type may be opposite to the second conductivity type. In this embodiment, the first conductivity type is N-type and the second conductivity type is P-type. Therefore, the first doped region P1-2 is a P-type heavily doped region P1-2, the second doped region P2-2 is a P-type heavily doped region P2-2, and the third doped region N1-2 is an N-type heavily doped region N1-2. In some embodiments, the first doped region P1-2 and the second doped region P2-2 may have the same doping concentration. In some embodiments, the doping concentration of third doped region N1-2 is greater than that of the first well region NW.

As shown in FIG. 5, the first doped region P1-2 and the second doped region P2-2 may be arranged side-by-side and located in the same active region 205-1 defined by the isolation features 201-1 and 201-2. The first doped region P1-2 and the second doped region P2-2 may be adjacent to the different isolation features 201-1 and 201-2. In addition, the first doped region N1-1 and the second doped region P2-2 may be spaced apart from each other in the direction 100. Furthermore, there is no isolation feature 201 between the first doped region P1-2 and the second doped region P2-2 in the direction 100.

As shown in FIG. 5, the third doped region N1-2 is located in the active region 205-2 defined by the isolation features 201-1 and 201-3. The first doped region P1-2 and the third doped region N1-2 may be arranged side-by-side and spaced apart from each other by the isolation feature 201-1 in the first well region NW. In addition, opposite side surfaces 201-1E1 and 201-1E2 of the isolation feature 201-1 are respectively adjacent to the first doped region P1-2 and the third doped region P2.

The gate structure 250 is disposed on the first well region NW. In addition, the gate structure 250 is located on a portion of the semiconductor substrate 200 between the first doped region P1-2 and the second doped region P2-2 in the direction 100 (the lateral direction). In addition, the gate structure 250 is adjacent to the first doped region P1-2 and the second doped region P2-2.

In some embodiments, the gate electrode layer of the gate structure 250 may be implanted with dopants. Alternatively, the gate electrode layer of the gate structure 250 may be formed without doping (undoped). In some embodiments, the conductivity type of the gate electrode layer of the gate structure 250 is different from the conductivity type of the first doped region P1-2 and the second doped region P2-2. In this embodiment, when the first doped region P1-2 and the second doped region P2-2 have the second conductivity type (e.g., P-type), the gate electrode layer of the gate structure 250 has the first conductivity type (e.g., N-type) or I-type (intrinsic).

As shown in FIG. 5, the electrostatic discharge protection device 500B is electrically connected between the ground terminal VSS and the power supply terminal VDD. The gate structure 250 is electrically connected to the first doped region P1-2 and the third doped region N1-2 directly by the conductive line 210. The conductive line 210 is electrically connected to the power supply terminal VDD. In other words, the gate structure 250, the first doped region P1-2 and the third doped region N1-2 are electrically connected to the power supply terminal VDD. In addition, the second doped region P2-2 is electrically connected to the ground terminal VSS directly by the conductive line 220.

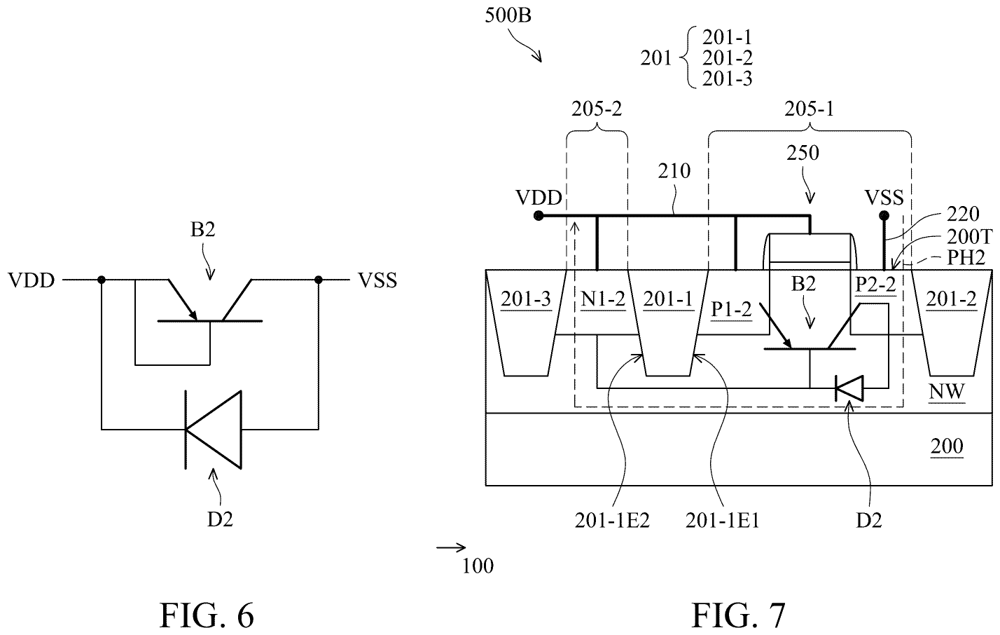

FIG. 6 is an equivalent discharge circuit diagram of the electrostatic discharge protection device 500B in accordance with some embodiments of the disclosure shown in FIG. 5, which shows the equivalent discharge circuit when an electrostatic discharge event occurs between the power supply terminal VDD and the ground terminal VSS, FIG. 7 is a schematic cross-sectional view showing the parasitic elements of the equivalent discharge circuit of FIG. 6 at the corresponding positions of the electrostatic discharge protection device 500B of FIG. 5. As shown in FIGS. 6 and 7, the equivalent discharge circuit in a condition that the electrostatic discharge event occurs between the power supply terminal VDD and the ground terminal VSS includes a parasitic bipolar junction transistor (BJT) B2 (for example, a parasitic PNP BJT) formed by the first doped region P1-2, the first well region NW and the second doped region P2-2. Emitter, base and collector of the parasitic bipolar junction transistor B2 are respectively formed by the first doped region P1-2, the first well region NW and the second doped region P2-2. The equivalent discharge circuit further includes a parasitic diode D2 formed by the second doped region P2-2, the first well region NW and the third doped region N1-2. Anode and cathode of the parasitic diode D2 are respectively formed by the second doped region P2-2 and the third doped region N1-2/the first well region NW.

As shown in FIGS. 6 and 7, the base (the first well region NW) of the parasitic bipolar junction transistor B2 is electrically connected to the emitter (the first doped region P1-2) of the parasitic bipolar junction transistor B2. The parasitic diode D2 is connected between the emitter (the first doped region P1-2) and the collector (the second doped region P2-2) of the parasitic bipolar junction transistor B2. More specifically, the anode (the second doped region P2-2) of the parasitic diode D2 is electrically connected to the collector (the second doped region P2-2) of the parasitic bipolar junction transistor B2. The cathode (the third doped region N1-2 and the first well region NW) of the parasitic diode D2 is electrically connected to the emitter (the first doped region P1-2) and the base (the first well region NW) of the parasitic bipolar junction transistor B2. The emitter (the first doped region P1-2) and the base (the first well region NW) of the parasitic bipolar junction transistor B2 and the cathode (the third doped region N1-2 and the first well region NW) of the parasitic diode D2 are electrically connected to the power supply terminal VDD by the conductive line 210. The collector (the second doped region P2-2) of the parasitic bipolar junction transistor B2 and the cathode (the second doped region P2-2) of the parasitic diode D2 are electrically connected to the ground terminal VSS by the conductive line 220.

On the other hand, the gate structure 250, the first well region NW, the first doped region P1-2, the second doped region P2-2 and the third doped region N1-2 may collectively form a first type metal-oxide-semiconductor field-effect transistor (MOS FET). The first type metal-oxide-semiconductor field-effect transistor (MOS FET) is formed in the first well region NW. In the first type metal-oxide-semiconductor field-effect transistor, the gate structure 250 serves as the gate of the first type metal-oxide-semiconductor field-effect transistor. The first doped region P1-2 may serve as the drain of the first type metal-oxide-semiconductor field-effect transistor. The second doped region P2-2 may serve as the source of the first type metal-oxide-semiconductor field-effect transistor. The third doped region N1-2 and the first well region NW may serve as the base (also called bulk) of the first type metal-oxide-semiconductor field-effect transistor.

In this embodiment, the gate (the gate structure 250), the drain (the first doped region P1-2) and the bulk (the third doped region N1-2 and the first well region NW) of the first type metal-oxide-semiconductor field-effect transistor are electrically connected to the power supply terminal VDD by the conductive line 210. The source (the second doped region P2-2) of the first type metal-oxide-semiconductor field-effect transistor is electrically connected to the ground terminal VSS by the conductive line 220. In this embodiment, the first conductivity type is N-type, the second conductivity type is P-type, and the first type metal-oxide-semiconductor field-effect transistor (MOS FET) is a P-type metal-oxide-semiconductor field-effect transistor (PMOS FET). The electrostatic discharge protection device 500B may serve as a gate-powered P-type metal-oxide-semiconductor field-effect transistor (GP PMOS FET).

In this embodiment, the source (the second doped region P2-2) and the drain (the first doped region P1-2) of the first type metal-oxide-semiconductor field-effect transistor (PMOS FET) and the first well region NW form the parasitic bipolar junction transistor B2. The source (the first doped region P1-2) of the first type metal-oxide-semiconductor field-effect transistor (PMOS FET) and the bulk (the third doped region N1-2 and the first well region NW) of the first type metal-oxide-semiconductor field-effect transistor (PMOS FET) form a parasitic diode D2.

Since the conductivity type of the gate electrode layer of the gate structure 250 is different from the conductivity type of the source (the second doped region P2-2) and the drain (the first doped region P1-2) of the first type metal-oxide-semiconductor field-effect transistor structure, the first type MOS FET structure may have a higher threshold voltage (Vt) in standby mode. The off current (Ioff) and drain-to-source leakage may be further reduced without additional fabrication cost (e.g., extra masks or larger device area).

When an electrostatic discharge event occurs at the power supply terminal VDD and the ground terminal VSS is grounded (or different input/output terminals IO to the power supply terminal VDD/the ground terminal VSS stress conditions), the emitter (the first doped region P1-2)-base (the first well region NW) junction of the parasitic bipolar junction transistor B2 will be in forward bias condition and the reverse-biased PN junction of the parasitic diode D2 will breakdown. In general, the parasitic bipolar junction transistor B2 has lower trigger voltage than the breakdown voltage of the parasitic diode D2. Therefore, the parasitic bipolar junction transistor B2 (the parasitic PNP BJT) is triggered to ON to form a current path PH2 from the power supply terminal VDD, through the parasitic bipolar junction transistor B2, and to the ground terminal VSS to discharge the electrostatic charges away from the internal circuit 400.

When an electrostatic discharge event occurs at the ground terminal VSS and the power supply terminal VDD is grounded, the parasitic diode D2 will be in forward bias condition to form a current path from the ground terminal VSS, through the parasitic diode D2, and to the power supply terminal VDD to discharge the electrostatic charges away from the internal circuit 400. The electrostatic discharge protection device 500B may provide bi-directional ESD protection.

When the internal circuit 400 in the system 600 is in normal operation (no electrostatic discharge event occurs), the electrostatic discharge protection device 500B is in the off-state. The base (the first well region NW)-emitter (the first doped region P1-2) junction of the parasitic bipolar junction transistor B2 is not in forward bias condition. In addition, the parasitic diode D2 is in reverse bias condition. Therefore, the parasitic bipolar junction transistor B2 and the parasitic diode D2 will not be triggered to ON. Furthermore, the electrostatic discharge protection device 500B is composed of the gate-powered P-type metal-oxide-semiconductor field-effect transistor (GP PMOS FET) with higher threshold voltage (Vt) in standby mode. The off current (Ioff) and drain-to-source leakage of the electrostatic discharge protection device 500B may be further reduced.

Embodiments provide an electrostatic discharge (ESD) protection device. The ESD protection device can discharge the electrostatic charges away from the internal circuits when the electrostatic discharge events occurs between the terminals of the power supply terminal VDD and the ground terminal VSS. The ESD protection device includes a semiconductor substrate, a first well region, a first doped region, a second doped region, a third doped region and a gate structure. The first well region having a first conductivity type is located in the semiconductor substrate. The first doped region having a second conductivity type is located on the first well region. The second doped region having the second conductivity type is located on the first well region. The first doped region and the second doped region are arranged side-by-side and spaced apart from each other. The third doped region having the first conductivity type is located on the first well region. The second doped region and the third doped region are located on opposite sides of the first doped region. The gate structure is disposed on the first well region and located on a portion of the semiconductor substrate between the first doped region and the second doped region. A conductivity type of the gate structure is different from a conductivity type of the first doped region and the second doped region. The gate structure is electrically connected to the first doped region and the third doped region.

In some embodiments, the gate structure has the first conductivity type. In some embodiments, the conductivity type of the gate structure is I-type. In some embodiments, the gate structure, the first doped region and the third doped region are electrically connected to a first terminal, and the second doped region is electrically connected to a second terminal. In some embodiments, the first doped region, the first well region and the second doped region form a first parasitic bipolar junction transistor. The second doped region, the first well region and the third doped region form a first parasitic diode. A base of the first parasitic bipolar junction transistor is electrically connected to an emitter of the first parasitic bipolar junction transistor, and the first parasitic diode is connected between the emitter and a collector of the first parasitic bipolar junction transistor.

In some embodiments, the first conductivity type is P-type, and the second conductivity type is N-type. In some embodiments, the gate structure, the first doped region and the third doped region are electrically connected to a ground terminal, and the second doped region is electrically connected to a power supply terminal. In some embodiments, an anode of the first parasitic diode is electrically connected to the emitter and the base of the first parasitic bipolar junction transistor, and a cathode of the first parasitic diode is electrically connected to the collector of the first parasitic bipolar junction transistor. When an electrostatic discharge event occurs at the second terminal (e.g., the power supply terminal VDD) and the first terminal (e.g., the ground terminal VSS) is grounded, the first parasitic bipolar junction transistor (the parasitic NPN BJT) is triggered to ON. When an electrostatic discharge event occurs at the first terminal (e.g., the ground terminal VSS) and the second terminal (e.g., the power supply terminal VDD) is grounded, the first parasitic diode is in forward bias condition.

In some embodiments, the first conductivity type is N-type, and the second conductivity type is P-type. In some embodiments, the gate structure, the first doped region and the third doped region are electrically connected to a power supply terminal, and the second doped region is electrically connected to a ground terminal. In some embodiments, an anode of the first parasitic diode is electrically connected to the collector of the first parasitic bipolar junction transistor, and a cathode of the first parasitic diode is electrically connected to the emitter and the base of the first parasitic bipolar junction transistor. When an electrostatic discharge event occurs at the first terminal (e.g., the power supply terminal VDD) and the second terminal (e.g., the ground terminal VSS) is grounded, the first parasitic bipolar junction transistor (the parasitic PNP BJT) is triggered to ON. When an electrostatic discharge event occurs at the second terminal (e.g., the ground terminal VSS) and the first terminal (e.g., the power supply terminal VDD) is grounded, the first parasitic diode is in forward bias condition.

On the other hand, the ESD protection device includes a semiconductor substrate, a first well region, and a first type metal-oxide-semiconductor field-effect transistor. The first well region having a first conductivity type is located in the semiconductor substrate. The first type metal-oxide-semiconductor field-effect transistor is formed in the first well region. A conductivity type of a gate of the first type metal-oxide-semiconductor field-effect transistor is different from a conductivity type of a source and a drain of the first type metal-oxide-semiconductor field-effect transistor. The gate and a bulk of the first type metal-oxide-semiconductor field-effect transistor are electrically connected to a first terminal.

In some embodiments, the first conductivity type is P-type, the first type metal-oxide-semiconductor field-effect transistor is an N-type metal-oxide-semiconductor field-effect transistor, and the gate structure is P-type or I-type. In some embodiments, the gate, the source and the bulk of the N-type metal-oxide-semiconductor field-effect transistor are electrically connected to a ground terminal, and the drain of the N-type metal-oxide-semiconductor field-effect transistor is electrically connected to a power supply terminal. In this embodiment, the electrostatic discharge protection devices may serve as a gate-grounded N-type metal-oxide-semiconductor field-effect transistor (GG NMOS FET).

In some embodiments, the source and the drain of the N-type metal-oxide-semiconductor field-effect transistor and the first well region form a first parasitic bipolar junction transistor. The drain of the N-type metal-oxide-semiconductor field-effect transistor and the bulk of the N-type metal-oxide-semiconductor field-effect transistor form a first parasitic diode. A base of the first parasitic bipolar junction transistor is electrically connected to an emitter of the first parasitic bipolar junction transistor. An anode of the first parasitic diode is electrically connected to the emitter and the base of the first parasitic bipolar junction transistor. A cathode of the first parasitic diode is electrically connected to the collector of the first parasitic bipolar junction transistor. When an electrostatic discharge event occurs at the power supply terminal, the first parasitic bipolar junction transistor (the parasitic NPN BJT) is triggered to ON. When an electrostatic discharge event occurs at the ground terminal, the first parasitic diode is in forward bias condition.

In some embodiments, the first conductivity type is N-type, the first type metal-oxide-semiconductor field-effect transistor is a P-type metal-oxide-semiconductor field-effect transistor, and the gate structure is N-type or I-type. In some embodiments, the gate, the drain and the bulk of the P-type metal-oxide-semiconductor field-effect transistor are electrically connected to a power supply terminal, and the source of the P-type metal-oxide-semiconductor field-effect transistor is electrically connected to a ground terminal. In this embodiment, the electrostatic discharge protection device may serve as a gate-powered P-type metal-oxide-semiconductor field-effect transistor (GP PMOS FET).

In some embodiments, the source and the drain of the P-type metal-oxide-semiconductor field-effect transistor and the first well region form a first parasitic bipolar junction transistor. The source of the P-type metal-oxide-semiconductor field-effect transistor and the bulk of the P-type metal-oxide-semiconductor field-effect transistor form a first parasitic diode. A base of the first parasitic bipolar junction transistor is electrically connected to an emitter of the first parasitic bipolar junction transistor. A cathode of the first parasitic diode is electrically connected to the emitter and the base of the first parasitic bipolar junction transistor. An anode of the first parasitic diode is electrically connected to the collector of the first parasitic bipolar junction transistor. When an electrostatic discharge event occurs at the input/output terminal, the first parasitic bipolar junction transistor (the parasitic PNP BJT) is triggered to ON. When an electrostatic discharge event occurs at the ground terminal, the first parasitic diode is in forward bias condition.

When the internal circuit in the system is in normal operation (no electrostatic discharge event occurs), the electrostatic discharge protection device is in the off-state. Furthermore, the electrostatic discharge protection device is composed of the gate-grounded N-type metal-oxide-semiconductor field-effect transistor (GG NMOS FET) or the gate-powered P-type metal-oxide-semiconductor field-effect transistor (GP PMOS FET) with higher threshold voltage (Vt) in standby mode. The off current (Ioff) and drain-to-source leakage may be further reduced without additional fabrication cost (e.g., extra masks or larger device area).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge protection device, comprising:
a semiconductor substrate;
a first well region having a first conductivity type located in the semiconductor substrate;
a first doped region having a second conductivity type located on the first well region;
a second doped region having the second conductivity type located on the first well region, wherein the first doped region and the second doped region are arranged side-by-side and spaced apart from each other; and
a third doped region having the first conductivity type located on the first well region, wherein the second doped region and the third doped region are located on opposite sides of the first doped region; and
a gate structure disposed on the first well region and located on a portion of the semiconductor substrate between the first doped region and the second doped region, wherein a conductivity type of the gate structure is different from a conductivity type of the first doped region and the second doped region,
wherein the gate structure is electrically connected to the first doped region and the third doped region.

2. The electrostatic discharge protection device as claimed in claim 1, wherein the gate structure, the first doped region and the third doped region are electrically connected to a first terminal, and the second doped region is electrically connected to a second terminal.

3. The electrostatic discharge protection device as claimed in claim 2, wherein:
the first doped region, the first well region and the second doped region form a first parasitic bipolar junction transistor,
the second doped region, the first well region and the third doped region form a first parasitic diode,
a base of the first parasitic bipolar junction transistor is electrically connected to an emitter of the first parasitic bipolar junction transistor, and the first parasitic diode is connected between the emitter and a collector of the first parasitic bipolar junction transistor.

4. The electrostatic discharge protection device as claimed in claim 3, wherein the first conductivity type is P-type, and the second conductivity type is N-type.

5. The electrostatic discharge protection device as claimed in claim 4, wherein the gate structure, the first doped region and the third doped region are electrically connected to a ground terminal, and the second doped region is electrically connected to a power supply terminal.

6. The electrostatic discharge protection device as claimed in claim 4, wherein an anode of the first parasitic diode is electrically connected to the emitter and the base of the first parasitic bipolar junction transistor, and a cathode of the first parasitic diode is electrically connected to the collector of the first parasitic bipolar junction transistor.

7. The electrostatic discharge protection device as claimed in claim 6, wherein when an electrostatic discharge event occurs at the second terminal and the first terminal is grounded, the first parasitic bipolar junction transistor is triggered to ON.

8. The electrostatic discharge protection device as claimed in claim 6, wherein when an electrostatic discharge event occurs at the first terminal and the second terminal is grounded, the first parasitic diode is in forward bias condition.

9. The electrostatic discharge protection device as claimed in claim 3, wherein the first conductivity type is N-type, and the second conductivity type is P-type.

10. The electrostatic discharge protection device as claimed in claim 9, wherein the gate structure, the first doped region and the third doped region are electrically connected to a power supply terminal, and the second doped region is electrically connected to a ground terminal.

11. The electrostatic discharge protection device as claimed in claim 9, wherein an anode of the first parasitic diode is electrically connected to the collector of the first parasitic bipolar junction transistor, and a cathode of the first parasitic diode is electrically connected to the emitter and the base of the first parasitic bipolar junction transistor.

12. The electrostatic discharge protection device as claimed in claim 9, wherein when an electrostatic discharge event occurs at the first terminal and the second terminal is grounded, the first parasitic bipolar junction transistor is triggered to ON.

13. The electrostatic discharge protection device as claimed in claim 9, wherein when an electrostatic discharge event occurs at the second terminal and the first terminal is grounded, the first parasitic diode is in forward bias condition.

14. The electrostatic discharge protection device as claimed in claim 1, wherein the gate structure has the first conductivity type.

15. The electrostatic discharge protection device as claimed in claim 1, wherein the conductivity type of the gate structure is I-type.

16. An electrostatic discharge protection device, comprising:
a semiconductor substrate;
a first well region having a first conductivity type located in the semiconductor substrate; and
a first type metal-oxide-semiconductor field-effect transistor formed in the first well region,
wherein a conductivity type of a gate of the first type metal-oxide-semiconductor field-effect transistor is different from a conductivity type of a source and a drain of the first type metal-oxide-semiconductor field-effect transistor,
and the gate and a bulk of the first type metal-oxide-semiconductor field-effect transistor are electrically connected to a first terminal.

17. The electrostatic discharge protection device as claimed in claim 16, wherein the first conductivity type is P-type, the first type metal-oxide-semiconductor field-effect transistor is an N-type metal-oxide-semiconductor field-effect transistor, and the gate structure is P-type or I-type.

18. The electrostatic discharge protection device as claimed in claim 17, wherein the gate, the source and the bulk of the N-type metal-oxide-semiconductor field-effect transistor are electrically connected to a ground terminal, and the drain of the N-type metal-oxide-semiconductor field-effect transistor is electrically connected to a power supply terminal.

19. The electrostatic discharge protection device as claimed in claim 18, wherein:
the source and the drain of the N-type metal-oxide-semiconductor field-effect transistor and the first well region form a first parasitic bipolar junction transistor,
the drain of the N-type metal-oxide-semiconductor field-effect transistor and the bulk of the N-type metal-oxide-semiconductor field-effect transistor form a first parasitic diode,
a base of the first parasitic bipolar junction transistor is electrically connected to an emitter of the first parasitic bipolar junction transistor,
an anode of the first parasitic diode is electrically connected to the emitter and the base of the first parasitic bipolar junction transistor, and
a cathode of the first parasitic diode is electrically connected to the collector of the first parasitic bipolar junction transistor.

20. The electrostatic discharge protection device as claimed in claim 19, wherein when an electrostatic discharge event occurs at the power supply terminal, the first parasitic bipolar junction transistor is triggered to ON.

21. The electrostatic discharge protection device as claimed in claim 19, wherein when an electrostatic discharge event occurs at the ground terminal, the first parasitic diode is in forward bias condition.

22. The electrostatic discharge protection device as claimed in claim 16, wherein the first conductivity type is N-type, the first type metal-oxide-semiconductor field-effect transistor is a P-type metal-oxide-semiconductor field-effect transistor, and the gate structure is N-type or I-type.

23. The electrostatic discharge protection device as claimed in claim 22, wherein the gate, the drain and the bulk of the P-type metal-oxide-semiconductor field-effect transistor are electrically connected to a power supply terminal, and the source of the P-type metal-oxide-semiconductor field-effect transistor is electrically connected to a ground terminal.

24. The electrostatic discharge protection device as claimed in claim 22, wherein:
the source and the drain of the P-type metal-oxide-semiconductor field-effect transistor and the first well region form a first parasitic bipolar junction transistor,
the source of the P-type metal-oxide-semiconductor field-effect transistor and the bulk of the P-type metal-oxide-semiconductor field-effect transistor form a first parasitic diode,
a base of the first parasitic bipolar junction transistor is electrically connected to an emitter of the first parasitic bipolar junction transistor,
a cathode of the first parasitic diode is electrically connected to the emitter and the base of the first parasitic bipolar junction transistor, and
an anode of the first parasitic diode is electrically connected to the collector of the first parasitic bipolar junction transistor.

25. The electrostatic discharge protection device as claimed in claim 24, wherein when an electrostatic discharge event occurs at the power supply terminal, the first parasitic bipolar junction transistor is triggered to ON.

26. The electrostatic discharge protection device as claimed in claim 24, wherein when an electrostatic discharge event occurs at the ground terminal, the first parasitic diode is in forward bias condition.
